(19) United States
(12) Patent Application Publication
(10) Pub. No.: US 2026/0090000 A1
(43) Pub. Date: Mar. 26, 2026

(54) SEMICONDUCTOR STRUCTURE AND MANUFACTURING METHOD THEREOF, AND HIGH ELECTRON MOBILITY TRANSISTOR AND MANUFACTURING METHOD THEREOF

(71) Applicant: NATIONAL TSING HUA UNIVERSITY, Hsinchu City (TW)

(72) Inventors: King-Yuen WONG, Hsinchu City (TW); Chun-Hao LAI, Hsinchu City (TW)

(21) Appl. No.: 19/054,614

(22) Filed: Feb. 14, 2025

(30) Foreign Application Priority Data
Sep. 20, 2024 (TW) 113135829

(51) Int. Cl. H10D 30/47; H10D 30/01; H10D 62/10; H10D 62/824

(52) U.S. Cl. CPC H10D 30/475; H10D 30/015; H10D 62/824; H10D 62/102

(57) ABSTRACT

A semiconductor structure includes a substrate, a channel layer, a barrier layer, a gate structure, a first passivation layer and a second passivation layer. The channel layer is disposed on the substrate. The barrier layer is disposed on the channel layer. The gate structure and the first passivation layer are disposed on the barrier layer. The second passivation layer is disposed on the first passivation layer, and a material composition of the second passivation layer is different from a material composition of the first passivation layer. The channel layer has two first two-dimensional electron gas regions near the barrier layer, and the first two-dimensional electron gas regions are located on two sides of the gate structure. The barrier layer has two second two-dimensional electron gas regions near the first passivation layer, and the second two-dimensional electron gas regions are located on two sides of the gate structure.

### RELATED APPLICATIONS

This application claims priority to Taiwan Application Serial Number 113135829, filed Sep. 20, 2024, which is herein incorporated by reference.

### BACKGROUND

### Technical Field

The present disclosure relates to a semiconductor structure and a manufacturing method thereof. More particularly, the present disclosure relates to a high electron mobility transistor including the semiconductor structure and a manufacturing method thereof.

### Description of Related Art

Although enhancement-mode high electron mobility transistor (E-mode HEMT) with p-GaN gate structure is the widely used high electron mobility transistor in the present industry, it cannot be effectively applied to low-voltage input applications, nor can it achieve the same effective scaling. E-mode HEMT with p-GaN gate structure loses its advantages over silicon-based devices when applied to input voltages below 10 V. Therefore, the traditional E-mode HEMT with p-GaN gate structure is no longer suitable for low-voltage input high-frequency and high-density buck converters.

In order to achieve enhancement-mode transistors, the gate structure of metal insulator semiconductor HEMT (MIS-HEMT) has been proposed and used to replace the p-GaN gate structure for low-voltage input applications. However, the gate structure of MIS-HEMT faces challenges due to gate recess etching, leading to issues such as non-uniform recess depth and interface defects. These problems result in performance variations of the device, including threshold voltage, on-resistance, and output current, as well as inconsistencies within and between chips. Consequently, these challenges pose significant difficulties for commercialization. In view of this, there is currently a lack of an enhancement-mode dual-channel transistor with great manufacturing repeatability and suitable for ultra-low voltage inputs on the market, so related industries want to solve currently.

### SUMMARY

According to one aspect of the present disclosure, a semiconductor structure includes a substrate, a channel layer, a barrier layer, a gate structure, a first passivation layer and a second passivation layer. The channel layer is disposed on the substrate. The barrier layer is disposed on the channel layer. The gate structure is disposed on the barrier layer. The first passivation layer is disposed on the barrier layer and in contact with a side surface of the gate structure. The second passivation layer is disposed on the first passivation layer, and a material composition of the second passivation layer is different from a material composition of the first passivation layer. The channel layer has two first two-dimensional electron gas regions near the barrier layer, and the two first two-dimensional electron gas regions are respectively located on two sides of the gate structure. The barrier layer has two second two-dimensional electron gas regions near the first passivation layer, and the two second two-dimensional electron gas regions are respectively located on the two sides of the gate structure.

According to another aspect of the present disclosure, a manufacturing method of a semiconductor structure includes providing a substrate and sequentially epitaxially growing a buffer layer, a channel layer, a barrier layer and a semiconductor layer on the substrate; depositing a metal layer on the semiconductor layer; etching the semiconductor layer and the metal layer to form a gate structure on the barrier layer; sequentially depositing a first passivation layer and a second passivation layer to cover the barrier layer and the gate structure; performing an annealing process to convert the first passivation layer from an amorphous structure to a crystal structure to form two first two-dimensional electron gas regions in the channel layer near the barrier layer and form two second two-dimensional electron gas regions in the barrier layer near the first passivation layer, wherein the two first two-dimensional electron gas regions are respectively located on two sides of the gate structure, and the two second two-dimensional electron gas regions are respectively located on the two sides of the gate structure; and etching the first passivation layer and the second passivation layer to expose a gate electrode of the gate structure.

According to yet another aspect of the present disclosure, a high electron mobility transistor includes a substrate, a channel layer, a barrier layer, a drain electrode, a source electrode, a gate structure, a first passivation layer, a second passivation layer and a protection layer. The channel layer is disposed on the substrate. The barrier layer is disposed on the channel layer. The drain electrode is disposed on the barrier layer. The source electrode is disposed on the barrier layer. The gate structure is disposed on the barrier layer and located between the drain electrode and the source electrode. The first passivation layer is disposed on the barrier layer. The second passivation layer is disposed on the first passivation layer. The protection layer covers the second passivation layer and the gate structure. The channel layer has two first two-dimensional electron gas regions near the barrier layer, and the two first two-dimensional electron gas regions are respectively located on two sides of the gate structure. The barrier layer has two second two-dimensional electron gas regions near the first passivation layer, and the two second two-dimensional electron gas regions are respectively located on the two sides of the gate structure.

According to yet another aspect of the present disclosure, a manufacturing method of a high electron mobility transistor includes providing a substrate and sequentially epitaxially growing a buffer layer, a channel layer, a barrier layer and a semiconductor layer on the substrate; depositing a metal layer on the semiconductor layer; etching the semiconductor layer and the metal layer to form a gate structure on the barrier layer; sequentially depositing a first passivation layer and a second passivation layer to cover the barrier layer and the gate structure; performing an annealing process to convert the first passivation layer from an amorphous structure to a crystal structure to form two first two-dimensional electron gas regions in the channel layer near the barrier layer and form two second two-dimensional electron gas regions in the barrier layer near the first passivation layer, wherein the two first two-dimensional electron gas regions are respectively located on two sides of the gate structure, and the two second two-dimensional electron gas regions are respectively located on the two sides of the gate structure; etching the first passivation layer and the second passivation layer to expose a gate electrode of the gate structure; depositing a protection layer to cover the second passivation layer and the gate electrode; etching the first passivation layer, the second passivation layer and the protection layer to form a first opening and a second opening; and forming a drain electrode on the barrier layer and in the first opening, and forming a source electrode on the barrier layer and in the second opening.

### BRIEF DESCRIPTION OF THE DRAWINGS

The patent or application file contains at least one drawing executed in color. Copies of this patent or patent application publication with color drawing(s) will be provided by Office upon request and payment of the necessary fee. The present disclosure can be more fully understood by reading the following detailed description of the embodiment, with reference made to the accompanying drawings as follows:

FIG. 1 shows a cross-sectional view of a semiconductor structure according to a first example of a first embodiment of the present disclosure.

FIG. 2 shows an energy band diagram of the semiconductor structure in FIG. 1 along the dot-dashed line A1-A2.

FIG. 3 shows an energy band diagram of the semiconductor structure in FIG. 1 along the dot-dashed line A3-A4.

FIG. 4 shows an electron concentration distribution diagram of the semiconductor structure in FIG. 1 under thermal equilibrium.

FIG. 5 shows a cross-sectional view of a semiconductor structure according to a second example of the first embodiment of the present disclosure.

FIG. 6 shows a flow chart of a manufacturing method of the semiconductor structure according to a second embodiment of the present disclosure.

FIG. 7A shows a cross-sectional view of the step of providing a substrate of the manufacturing method of the semiconductor structure in FIG. 6.

FIG. 7B shows a cross-sectional view of the step of depositing a metal layer of the manufacturing method of the semiconductor structure in FIG. 6.

FIG. 7C shows a cross-sectional view of the step of forming a gate structure of the manufacturing method of the semiconductor structure in FIG. 6.

FIG. 7D shows a cross-sectional view of the step of depositing a first passivation layer and a second passivation layer and the step of performing an annealing process of the manufacturing method of the semiconductor structure in FIG. 6.

FIG. 7E shows a cross-sectional view of the step of etching the first passivation layer and the second passivation layer of the manufacturing method of the semiconductor structure in FIG. 6.

FIG. 8 shows a cross-sectional view of a high electron mobility transistor according to a first example of a third embodiment of the present disclosure.

FIG. 9 shows a cross-sectional view of a high electron mobility transistor according to a second example of the third embodiment of the present disclosure.

FIG. 10 shows a flow chart of a manufacturing method of the high electron mobility transistor according to a fourth embodiment of the present disclosure.

FIG. 11A shows a cross-sectional view of the step of obtaining a semiconductor structure of the manufacturing method of the high electron mobility transistor in FIG. 10.

FIG. 11B shows a cross-sectional view of the step of depositing a protection layer of the manufacturing method of the high electron mobility transistor in FIG. 10.

FIG. 11C shows a schematic cross-sectional view of the step of forming a first opening and a second opening of the manufacturing method of the high electron mobility transistor in FIG. 10.

FIG. 11D shows a schematic cross-sectional view of a first sub-step of the step of forming a drain electrode and a source electrode of the manufacturing method of the high electron mobility transistor in FIG. 10.

FIG. 11E shows a schematic cross-sectional view of a second sub-step of the step of forming the drain electrode and the source electrode of the manufacturing method of the high electron mobility transistor in FIG. 10.

### DETAILED DESCRIPTION

The embodiment will be described with the drawings. For clarity, some practical details will be described below. However, it should be noted that the present disclosure should not be limited by the practical details, that is, in some embodiment, the practical details is unnecessary. In addition, for simplifying the drawings, some conventional structures and elements will be simply illustrated, and repeated elements may be represented by the same labels.

It will be understood that when an element (or device) is referred to as be “connected” to another element, it can be directly connected to the other element, or it can be indirectly connected to the other element, that is, intervening elements may be present. In contrast, when an element is referred to as be “directly connected to” another element, there are no intervening elements present. In addition, the terms first, second, third, etc. are used herein to describe various elements or components, these elements or components should not be limited by these terms. Consequently, a first element or component discussed below could be termed a second element or component.

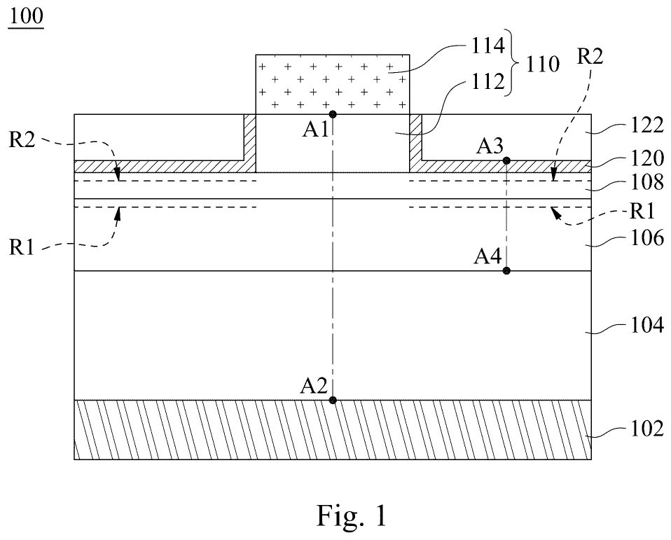

Please refer to FIG. 1. FIG. 1 shows a cross-sectional view of a semiconductor structure 100 according to a first example of a first embodiment of the present disclosure. As shown in FIG. 1, the semiconductor structure 100 can be part of a transistor, and the transistor can be, but is not limited to, a high electron mobility transistor (HEMT). The semiconductor structure 100 includes a substrate 102, a buffer layer 104, a channel layer 106, a barrier layer 108, a gate structure 110, a first passivation layer 120 and a second passivation layer 122.

The buffer layer 104 and the channel layer 106 are disposed on the substrate 102, and the buffer layer 104 is disposed between the substrate 102 and the channel layer 106, that is, the channel layer 106 is disposed on the buffer layer 104. The barrier layer 108 is disposed on the channel layer 106. The gate structure 110 is disposed on the barrier layer 108. The first passivation layer 120 is disposed on the barrier layer 108 and in contact with a side surface of the gate structure 110. The second passivation layer 122 is disposed on the first passivation layer 120. Specifically, the buffer layer 104, the channel layer 106, the barrier layer 108 and a semiconductor layer 112 of the gate structure 110 can form an epitaxial structure, and the epitaxial structure can be epitaxially grown on the substrate 102 through an epitaxial growth process.

In some embodiments, the substrate 102 can be a semiconductor substrate, such as a silicon substrate. The substrate 102 can include various film layers, such as conductive layers or insulating layers formed on the semiconductor substrate. In some embodiments, the substrate 102 can include various doping configurations according to design requirements recognized in the prior art. The substrate 102 can include other basic semiconductor materials, such as germanium (Ge). Alternatively, the substrate 102 can include a compound semiconductor, such as sapphire, silicon carbide (SiC), gallium arsenide (GaAs), gallium nitride (GaN), indium arsenide (InAs), and/or indium phosphide (InP). The substrate 102 can include alloy semiconductors, such as silicon germanium (SiGe), gallium arsenide phosphide (GaAsP), and gallium indium phosphide (GaInP). In some embodiments, the substrate 102 can also include a silicon on insulator (SOI) structure and/or have other suitable reinforcement components.

In some embodiments, the buffer layer 104 can include a group III-nitride compound semiconductor, which can be but is not limited to, gallium nitride (GaN). In some embodiments, the buffer layer 104 can include a single layer or multiple layers, and the thickness of the buffer layer 104 can range from 500 nanometers (nm) to 2000 nm. The buffer layer 104 can be configured to reduce the lattice mismatch between the substrate 102 and the channel layer 106, such as providing additional lattice matching and/or inhibiting the diffusion of electrons from the substrate 102 into the channel layer 106.

In some embodiments, the channel layer 106 can include a binary III-V semiconductor, which can be but is not limited to, gallium nitride (GaN) or a similar compound semiconductor. The thickness of the channel layer 106 can range from 200 nm to 800 nm. In some embodiments, the channel layer 106 can be undoped or doped (e.g., n-type or p-type), wherein the channel layer 106 having been doped can be configured to increase the breakdown voltage of the semiconductor structure 100.

In some embodiments, the barrier layer 108 can include a ternary III-V compound semiconductor, which can be but is not limited to, aluminum gallium nitride (AlGaN). In other words, the barrier layer 108 can be a ternary III-V compound barrier layer, which can be but is not limited to, aluminum gallium nitride (AlGaN) layer. In addition, the barrier layer 108 can have a chemical formula of AlₓGa₍₁₋ₓ₎N, wherein x can be less than 10%, that is, an aluminum atomic concentration of the barrier layer 108 can be less than 10%. In some embodiments, the barrier layer 108 can have a thickness less than 10 nm; preferably, the thickness of barrier layer 108 can be 8 nm.

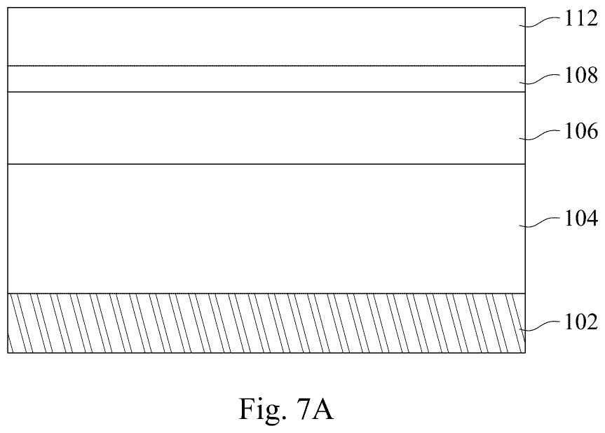

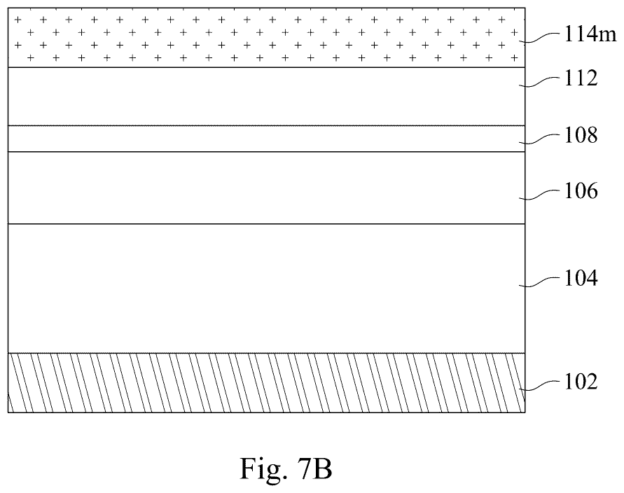

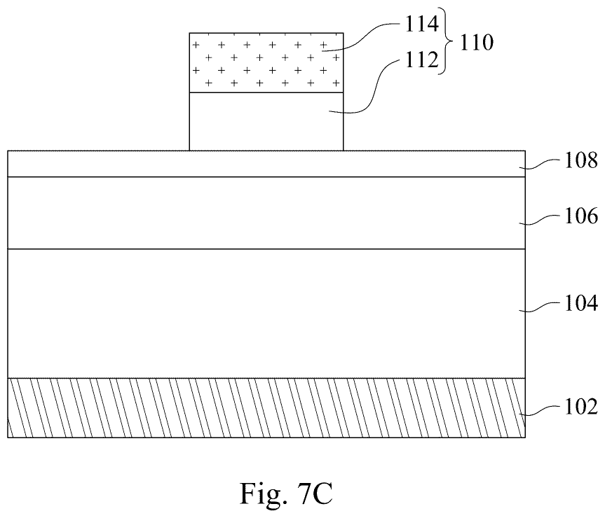

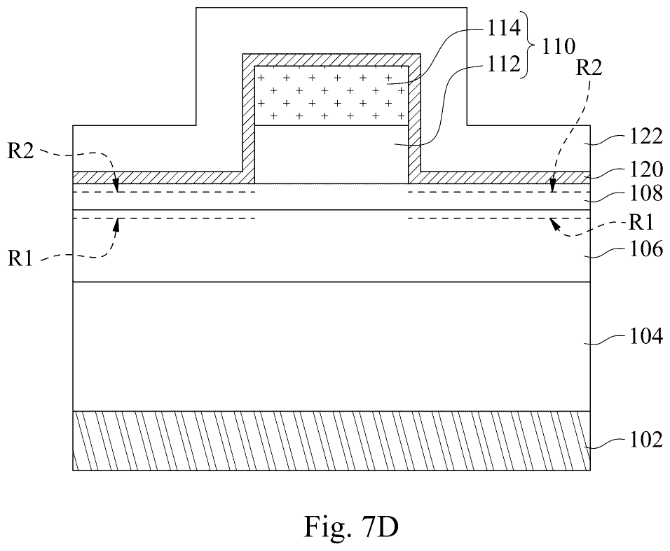

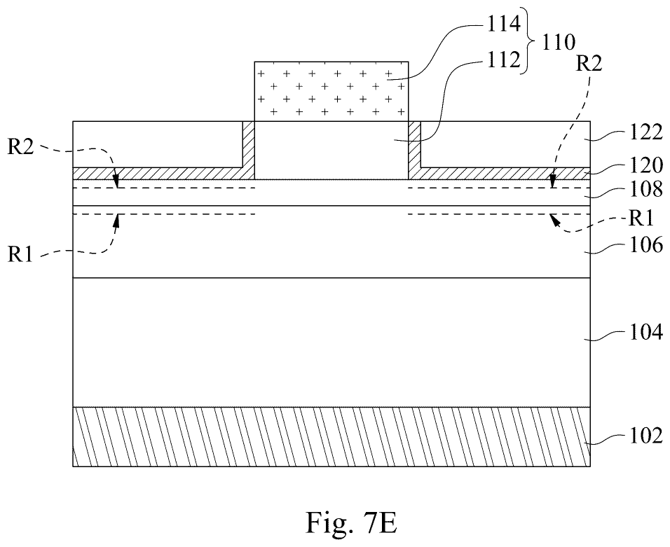

In some embodiments, the gate structure 110 can include the semiconductor layer 112 and a gate electrode 114. The semiconductor layer 112 is disposed on the barrier layer 108. The gate electrode 114 is disposed on the semiconductor layer 112, and the width of the gate electrode 114 is the same as the width of the semiconductor layer 112. In some embodiments, the semiconductor layer 112 can include an undoped III-V compound semiconductor, which can be but is not limited to, undoped gallium nitride (GaN); in other words, the semiconductor layer 112 can be an undoped III-V compound semiconductor layer, which can be but is not limited to, an undoped gallium nitride (GaN) layer. The semiconductor layer 112 can have a thickness ranging from 30 nm to 80 nm. In some embodiments, the gate electrode 114 can be made of a metal layer 114 m (as shown in FIG. 7B), and the thickness of the metal layer 114 m can range from 5 nm to 500 nm. The metal layer 114 m can be patterned through a photolithography process and an etching process to form the gate electrode 114. In addition, the material of the gate electrode 114 (i.e., the metal layer 114 m) can be a conductive metal material, which can be but is not limited to, silver (Ag), aluminum (Al), tungsten (W), nickel (Ni), gold (Au), titanium (Ti), titanium nitride (TiN), titanium aluminum nitride (TiAlN) or other suitable metal materials and combinations thereof.

In some embodiments, the first passivation layer 120 can be conformally formed over the barrier layer 108 through a deposition process, and then patterned through the photolithography process and the etching process. The first passivation layer 120 is in contact with a sidewall of the semiconductor layer 112 directly. The second passivation layer 122 can be conformally formed through the deposition process over the first passivation layer 120, and then patterned through the photolithography process and the etching process. The second passivation layer 122 is configured to protect the first passivation layer 120 during the process. In order to protect the first passivation layer 120, the thickness of the second passivation layer 122 can be greater than the thickness of the first passivation layer 120. In addition, a material composition of the second passivation layer 122 is different from a material composition of the first passivation layer 120. In some embodiments, the first passivation layer 120 can be, but is not limited to, an aluminum nitride (AlN) layer, and its thickness can be less than 15 nm. The second passivation layer 122 can be, but is not limited to, an oxide layer (e.g., SiO₂) or a nitride layer (e.g., SiN), and its thickness can be between 30 nm and 300 nm.

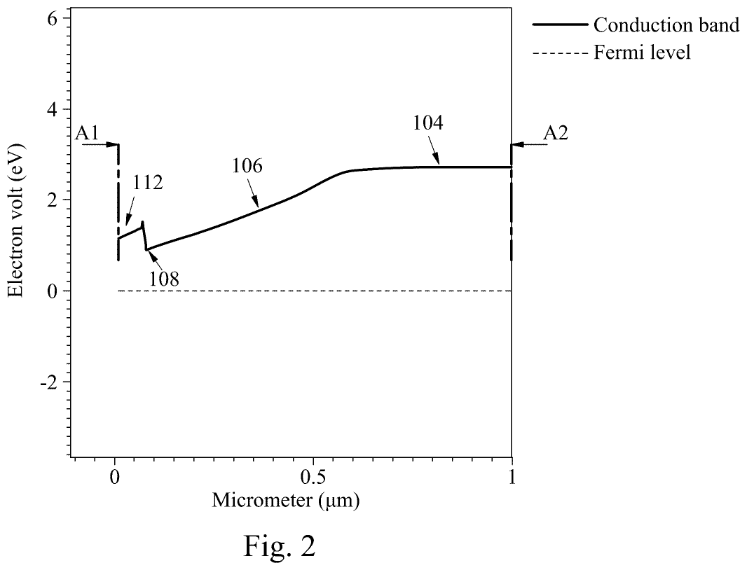

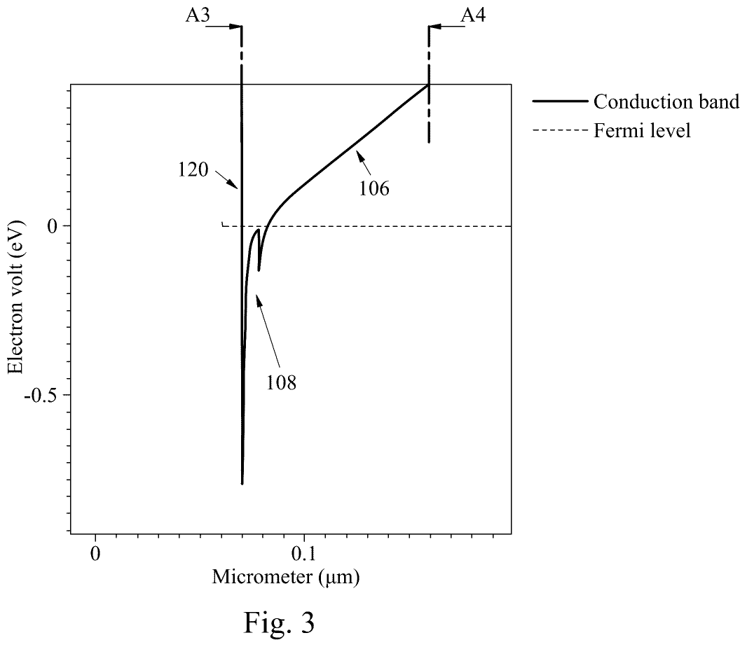

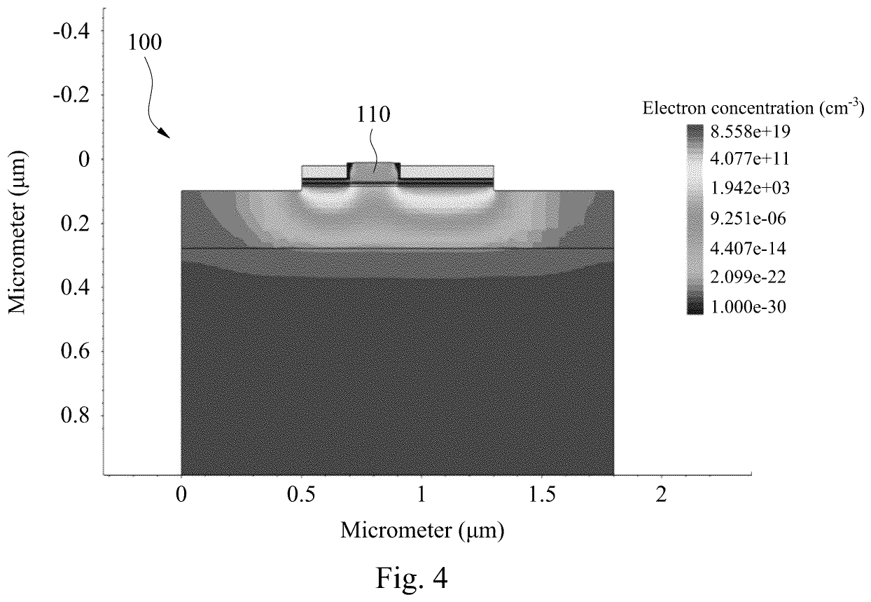

Please refer to FIGS. 1, 2, 3 and 4. FIG. 2 shows an energy band diagram of the semiconductor structure 100 in FIG. 1 along the dot-dashed line A1-A2. FIG. 3 shows an energy band diagram of the semiconductor structure 100 in FIG. 1 along the dot-dashed line A3-A4. FIG. 4 shows an electron concentration distribution diagram of the semiconductor structure 100 in FIG. 1 under thermal equilibrium.

As shown in FIGS. 1 and 2, the epitaxial structure in the semiconductor structure 100 can include a first stacked structure composed of the semiconductor layer 112, the barrier layer 108, the channel layer 106 and the buffer layer 104 along the dot-dashed line A1-A2. The conduction band of the first stacked structure is higher than the Fermi level. In other words, without the conduction band being lower than the Fermi level, two-dimensional electron gas (2DEG) cannot be formed in the epitaxial structure in the semiconductor structure 100. It should be noted that, there is a high concentration of 2DEG between the gate structure and the barrier layer due to a heterojunction between the gate structure and the barrier layer in the gate stack of the prior art. Different from the gate stack of the prior art, since the thickness of the barrier layer 108 of the present disclosure is thin (8 nm) and the aluminum atomic concentration of the barrier layer 108 is low (<10%), 2DEG concentration on the surface of the barrier layer 108 can be reduced, so that no carrier channel is formed under the gate structure 110. Therefore, the semiconductor structure 100 of the present disclosure can achieve enhancement-mode effects in the device. Further, the semiconductor layer 112 of the gate structure 110 is the undoped gallium nitride (GaN) layer, which can be configured to increase the threshold voltage of the transistor including the semiconductor structure 100.

In some embodiments, the channel layer 106 can have two first two-dimensional electron gas regions R1 near the barrier layer 108, and the two first two-dimensional electron gas regions R1 are respectively located on two sides of the gate structure 110. The barrier layer 108 can have two second two-dimensional electron gas regions R2 near the first passivation layer 120, and the two second two-dimensional electron gas regions R2 are respectively located on the two sides of the gate structure 110. In some embodiments, the first passivation layer 120 can be converted from an amorphous state to a crystalline state after an annealing process, thereby adjusting the energy band structure below the first passivation layer 120. Based on the recrystallized first passivation layer 120, not only can be the 2DEG concentration between the barrier layer 108 and the channel layer 106 increased to form the first two-dimensional electron gas region R1, but the 2DEG concentration between the first passivation layer 120 and the barrier layer 108 can also be increased to form the second two-dimensional electron gas region R2. Therefore, the semiconductor structure 100 of the present disclosure can have a dual-channel effect and achieve high electron mobility.

In detail, the first passivation layer 120 can be amorphous after the deposition process, but after the annealing process, the first passivation layer 120 is converted from amorphous to polycrystalline. Therefore, the first passivation layer 120 becomes a conductive thin film. The main purpose of performing the annealing process on the first passivation layer 120 is to improve the quality of the interface between the first passivation layer 120 and the barrier layer 108, so that the first passivation layer 120 can not only prevent leakage current of the gate structure 110, but also adjust the energy band structure of the barrier layer 108, the channel layer 106 and the buffer layer 104 located below the first passivation layer 120.

As shown in FIGS. 1 and 3, the semiconductor structure 100 can include a second stacked structure composed of the first passivation layer 120, the barrier layer 108 and the channel layer 106 along the dot-dashed line A3-A4. In the second stacked structure, the conduction band of the interface between the first passivation layer 120 and the barrier layer 108 is lower than the Fermi level, and the conduction band of the interface between the barrier layer 108 and the channel layer 106 is lower than the Fermi level. In other words, the first two-dimensional electron gas region R1 can be formed adjacent to the interface between the barrier layer 108 and the channel layer 106, and the second two-dimensional electron gas region R2 can be formed adjacent to the interface between the first passivation layer 120 and the barrier layer 108. As shown in FIG. 4, under thermal equilibrium (i.e., zero bias), since the semiconductor structure 100 has the first two-dimensional electron gas regions R1 and the second two-dimensional electron gas regions R2, both sides of the gate structure 110 (i.e., an area below the first passivation layer 120) are much higher than the electron concentration in an area below the gate structure 110. Therefore, the enhancement-mode semiconductor device using the semiconductor structure 100 as a basic structure can have ultra-low voltage input and dual-channel characteristics.

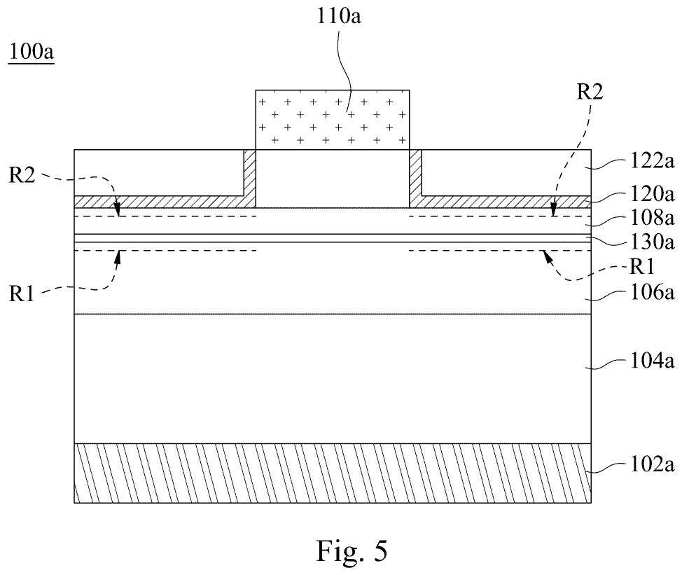

Please refer to FIG. 5. FIG. 5 shows a cross-sectional view of a semiconductor structure 100a according to a second example of the first embodiment of the present disclosure. As shown in FIG. 5, the semiconductor structure 100a can include a substrate 102a, a buffer layer 104a, a channel layer 106a, a barrier layer 108a, a gate structure 110a, a first passivation layer 120a, and a second passivation layer 122a, which are the same as the corresponding components in the semiconductor structure 100 in FIG. 1 and not described again herein.

In some embodiments, the semiconductor structure 100a can further include a spacer layer 130a. The spacer layer 130a is disposed between the channel layer 106a and the barrier layer 108a. Specifically, the spacer layer 130a can be, but is not limited to, an aluminum nitride (AlN) layer, the thickness of which can be 1 nm. The barrier layer 108a can have a thickness of 7 nm. The spacer layer 130a is mainly configured to increase the 2DEG concentration, thereby increasing the conductivity of the first two-dimensional electron gas regions R1 and the second two-dimensional electron gas regions R2. Thus, by disposing a binary nitride intermediate layer with lower energy gap (i.e., the spacer layer 130a) between the channel layer 106a and the barrier layer 108a, the sheet carrier concentration in the first two-dimensional electron gas regions R1 and the second two-dimensional electron gas regions R2 of the semiconductor structure 100a can be increased, thereby increasing the electron mobility.

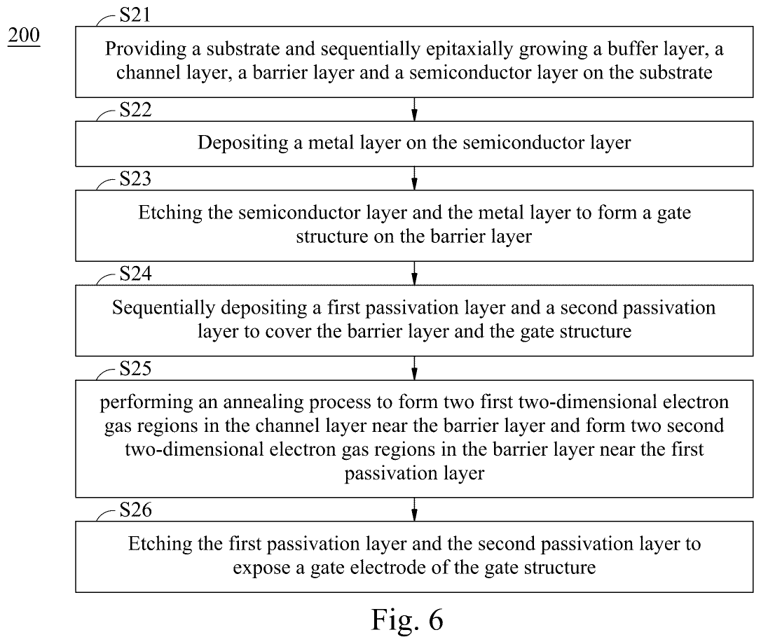

A manufacturing method of the semiconductor structure 100 of the present disclosure is described in more detail with the drawings and the embodiments below. Please refer to FIGS. 1, 6, 7A, 7B, 7C, 7D and 7E. FIG. 6 shows a flow chart of a manufacturing method 200 of a semiconductor structure according to a second embodiment of the present disclosure. FIG. 7A shows a cross-sectional view of Step S21 of providing the substrate 102 of the manufacturing method 200 of the semiconductor structure in FIG. 6. FIG. 7B shows a cross-sectional view of Step S22 of depositing the metal layer 114 m of the manufacturing method 200 of the semiconductor structure in FIG. 6. FIG. 7C shows a cross-sectional view of Step S23 of forming the gate structure 110 of the manufacturing method 200 of the semiconductor structure in FIG. 6. FIG. 7D shows a cross-sectional view of Step S24 of depositing the first passivation layer 120 and the second passivation layer 122 and Step S25 of performing the annealing process of the manufacturing method 200 of the semiconductor structure in FIG. 6. FIG. 7E shows a cross-sectional view of Step 26 of etching the first passivation layer 120 and the second passivation layer 122 of the manufacturing method 200 of the semiconductor structure in FIG. 6.

As shown in FIG. 6, the manufacturing method 200 of the semiconductor structure (hereinafter referred to as “the manufacturing method 200”) can be used to manufacture the semiconductor structure 100 of FIG. 1, and includes Step S21, Step S22, Step S23, Step S24, Step S25 and Step S26.

As shown in FIGS. 6 and 7, Step S21: providing a substrate 102 and sequentially epitaxially growing a buffer layer 104, a channel layer 106, a barrier layer 108 and a semiconductor layer 112 on the substrate 102 through the epitaxial growth process. In Step S21, the epitaxial growth process can be, for example, a molecular beam epitaxy (MBE) process, a metal-organic chemical vapor deposition (MOCVD) process, or other suitable epitaxial growth processes. In other embodiments, an epitaxial wafer including a buffer layer, a channel layer, a barrier layer and a semiconductor layer can also be directly obtained.

As shown in FIGS. 6 and 7B, Step S22: depositing a metal layer 114m on the semiconductor layer 112 through a deposition process. In step S22, the deposition process can be, for example, chemical vapor deposition (CVD), physical vapor deposition (PVD), electroplating or other suitable deposition processes.

As shown in FIGS. 6 and 7C, Step S23: etching the semiconductor layer 112 and the metal layer 114m to form a gate structure 110 on the barrier layer 108. In some embodiments, Step S23 can include a first sub-step and a second sub-step. The first sub-step is to perform the photolithography process to deposit a photoresist layer on the metal layer 114m and pattern the photoresist layer to form a photomask (not shown). The photolithography process can include multiple processes, such as spin coating, soft bake, exposure, development and hard bake. The photomask can be transferred to the metal layer 114m through the photolithography process. The second sub-step is to perform an anisotropic etching process to etch the region of the metal layer 114m that is not covered by the photomask to form the gate electrode 114 of the gate structure 110, and etch the semiconductor layer 112 that is not covered by the photomask to form the semiconductor layer 112 of the gate structure 110, and then remove the photomask through a photoresist lift-off process, wherein the gate electrode 114 and the sidewalls of the semiconductor layer 112 are shown to be vertically aligned or coplanar.

As shown in FIGS. 6 and 7D, Step S24: sequentially depositing a first passivation layer 120 and a second passivation layer 122 to cover the barrier layer 108 and the gate structure 110. In Step S24, the deposition process for forming the first passivation layer 120 can be different from the deposition process for forming the second passivation layer 122. The first passivation layer 120 can be conformally formed over the barrier layer 108 and the gate structure 110 through an atomic layer deposition (ALD) process or the MOCVD process. The second passivation layer 122 can be conformally formed over the first passivation layer 120 through the CVD process or a plasma-enhanced chemical vapor deposition (PECVD) process. Since the deposition speed of the second passivation layer 122 is faster than the deposition speed of the first passivation layer 120, excellent process productivity can be maintained.

Step S25: performing an annealing process to convert the first passivation layer 120 from an amorphous structure to a crystal structure to form two first two-dimensional electron gas regions R1 in the channel layer 106 near the barrier layer 108 and form two second two-dimensional electron gas regions R2 in the barrier layer 108 near the first passivation layer 120, wherein the two first two-dimensional electron gas regions R1 are respectively located on two sides of the gate structure 110, and the two second two-dimensional electron gas regions R2 are respectively located on the two sides of the gate structure 110.

As shown in FIGS. 6 and 7E, Step S26: etching the first passivation layer 120 and the second passivation layer 122 to expose a gate electrode 114 of the gate structure 110 through the etching process. In Step S26, the etching process can be the anisotropic etching process, and the first passivation layer 120 and the second passivation layer 122 are selectively etched to a plane flush with the upper surface of the semiconductor layer 112, wherein the first passivation layer 120 can have an L-shape, and a part of the first passivation layer 120 is in contact with the sidewall of the semiconductor layer 112. Thus, the manufacturing method 200 of the present disclosure can reduce the 2DEG under the gate structure 110 by adjusting the configuration of the epitaxial structure in the semiconductor structure 100, such as thinning the thickness of the barrier layer 108 and reducing the proportion of aluminum atoms in the barrier layer 108. Therefore, the semiconductor structure 100 can achieve enhancement-mode effects, and the manufacturing repeatability of the semiconductor structure 100 can be excellent. In addition, the annealing process can be used to recrystallize the first passivation layer 120 disposed on the barrier layer 108, and the crystallized first passivation layer 120 can adjust the energy band structure below it to generate the first two-dimensional electron gas regions R1 and the second two-dimensional electron gas regions R2. Based on the dual channel formed by the first two-dimensional electron gas regions R1 and the second two-dimensional electron gas regions R2, the current of the semiconductor structure 100 can be increased.

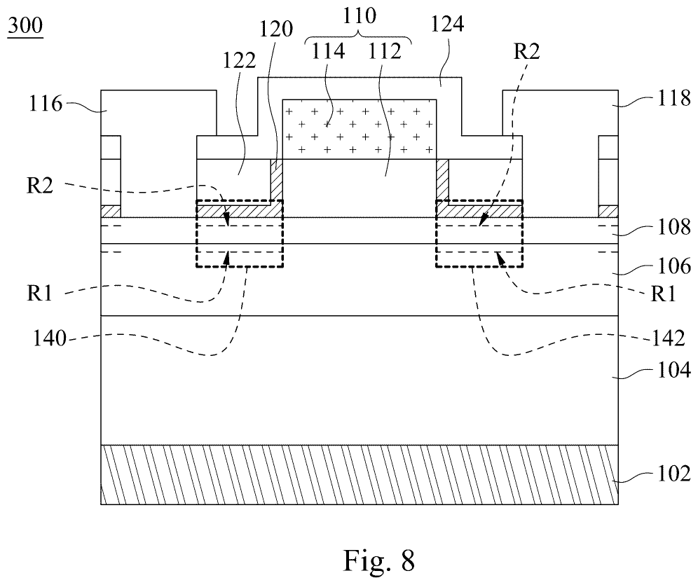

Please refer to FIGS. 1 and 8. FIG. 8 shows a cross-sectional view of a high electron mobility transistor 300 according to a first example of a third embodiment of the present disclosure. As shown in FIG. 8, the high electron mobility transistor 300 includes a substrate 102, a buffer layer 104, a channel layer 106, a barrier layer 108, a gate structure 110, a drain electrode 116, a source electrode 118, a first passivation layer 120, a second passivation layer 122 and a protection layer 124. Specifically, the high electron mobility transistor 300 is an enhancement-mode gallium nitride high electron mobility transistor (E-mode GaN HEMT) composed of the semiconductor structure 100 in FIG. 1, that is, the high electron mobility transistor 300 is an E-mode HEMT with undoped gallium nitride (GaN). In other words, the drain electrode 116, the source electrode 118 and the protection layer 124 of the high electron mobility transistor 300 can be formed on the semiconductor structure 100. Therefore, components in the high electron mobility transistor 300 in FIG. 8 that are the same as those in the semiconductor structure 100 in FIG. 1 use the same component numbers. Please refer to the above descriptions of the same the same components are not described again herein.

In FIG. 8, all of the gate structure 110, the drain electrode 116 and the source electrode 118 are disposed on the barrier layer 108, and the gate structure 110 is located between the drain electrode 116 and the source electrode 118. The protection layer 124 covers a part of the first passivation layer 120, the second passivation layer 122 and the gate structure 110. In some embodiments, the material of the protection layer 124 can be a dielectric material, such as silicon dioxide (SiO₂), silicon nitride (SiN), silicon oxynitride (SiON), low dielectric constant materials or other suitable dielectric materials.

The channel layer 106 can have two first two-dimensional electron gas regions R1 near the barrier layer 108, and the two first two-dimensional electron gas regions R1 are respectively located on two sides of the gate structure 110. The barrier layer 108 can have two second two-dimensional electron gas regions R2 near the first passivation layer 120, and the two second two-dimensional electron gas regions R2 are respectively located on the two sides of the gate structure 110. In some embodiments, a first access region 140 can be formed between the drain electrode 116 and the gate structure 110, and a second access region 142 can be formed between the source electrode 118 and the gate structure 110. The two first two-dimensional electron gas regions R1 are respectively located in the first access region 140 and the second access region 142, and the two second two-dimensional electron gas regions R2 are respectively located in the first access region 140 and the second access region 142. In detail, the first access region 140 and the second access region 142 refer to two access regions in the transistor, wherein one of the access regions is located between the drain and the gate and the other access region is located between the source and the gate. Thus, the high electron mobility transistor 300 of the present disclosure can realize an E-mode HEMT without using p-GaN gate structure by adjusting the configuration of the epitaxial structure in the semiconductor structure 100. In addition, the energy band structure below the first passivation layer 120 can be adjusted by depositing the first passivation layer 120 on the barrier layer 108, so that the first two-dimensional electron gas regions R1 and the second two-dimensional electron gas regions R2 are formed into the dual channel in the first access region 140 and the second access region 142 to achieve the effect of improving device performance.

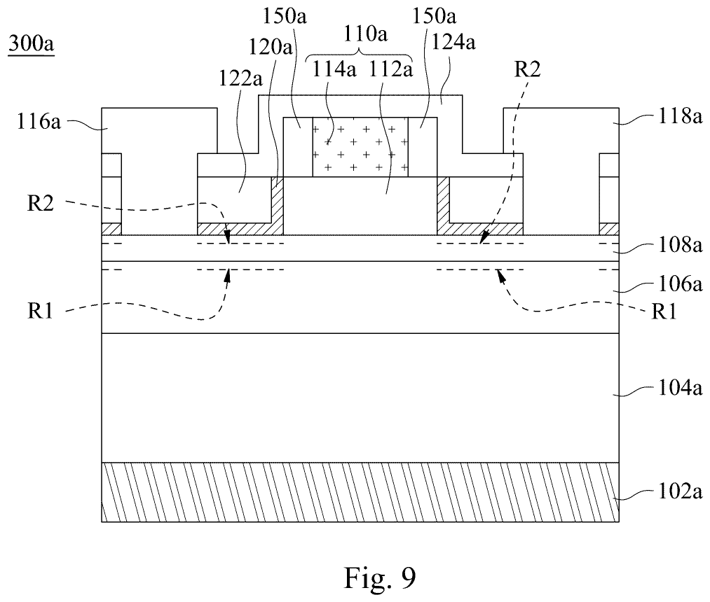

Please refer to FIG. 9. FIG. 9 shows a cross-sectional view of a high electron mobility transistor 300a according to a second example of the third embodiment of the present disclosure. As shown in FIG. 9, the high electron mobility transistor 300a includes a substrate 102a, a buffer layer 104a, a channel layer 106a, a barrier layer 108a, a gate structure 110a, a drain electrode 116a, a source electrode 118a, a first passivation layer 120a, a second passivation layer 122a and a protection layer 124a, which are the same as the corresponding components in the high electron mobility transistor 300 in FIG. 8 and not described again herein.

In some embodiments, the high electron mobility transistor 300a can further include a gate spacer 150a. The gate spacer 150a and the gate electrode 114a are disposed on the semiconductor layer 112a, and the width of the gate electrode 114a is smaller than the width of the semiconductor layer 112a. The gate spacer 150a is in contact with two opposite sidewalls of the gate electrode 114a and can be configured to protect the gate electrode 114a to prevent excessive electric field. In some embodiments, the deposition process for forming the gate spacer 150a can be, for example, a chemical vapor deposition (CVD) process, a physical vapor deposition (PVD) process, an atomic layer deposition (ALD) process, or a plasma-enhanced chemical vapor deposition (PECVD) process. The material of the gate spacer 150a can be a high dielectric constant material, such as aluminum nitride (AlN), aluminum oxide (Al₂O₃) or similar materials.

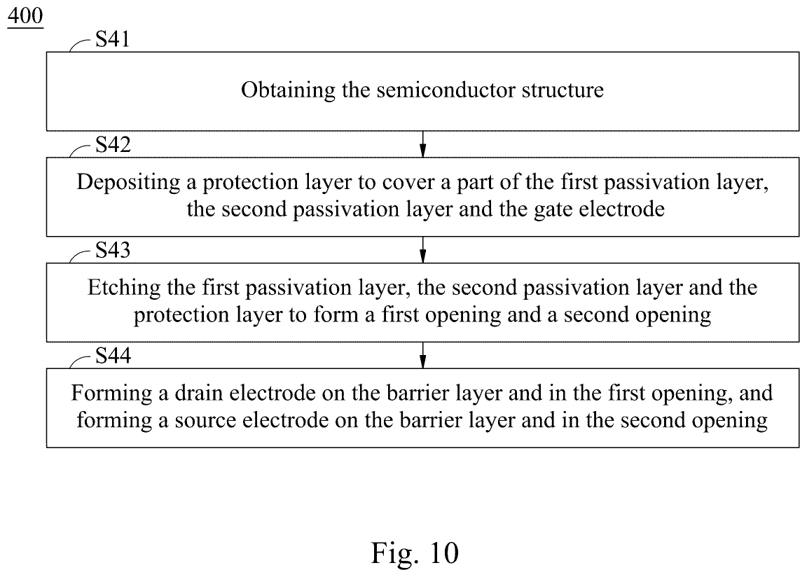

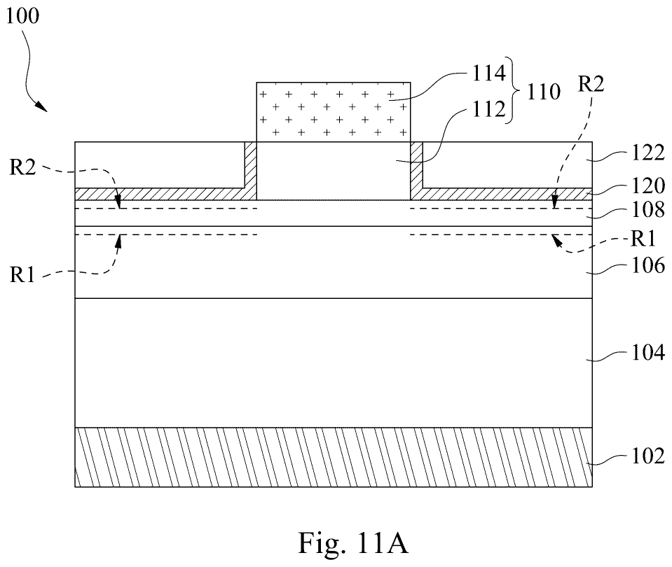

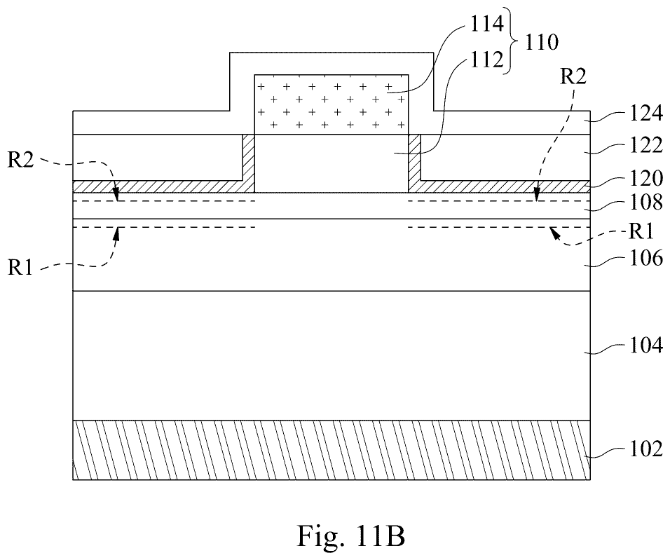

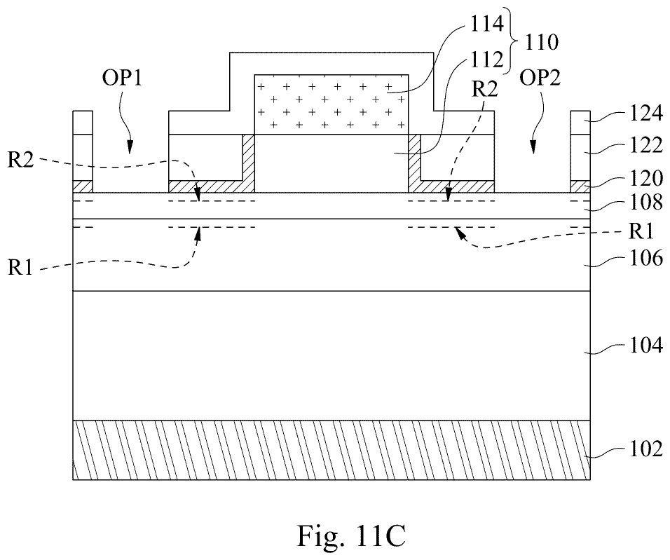

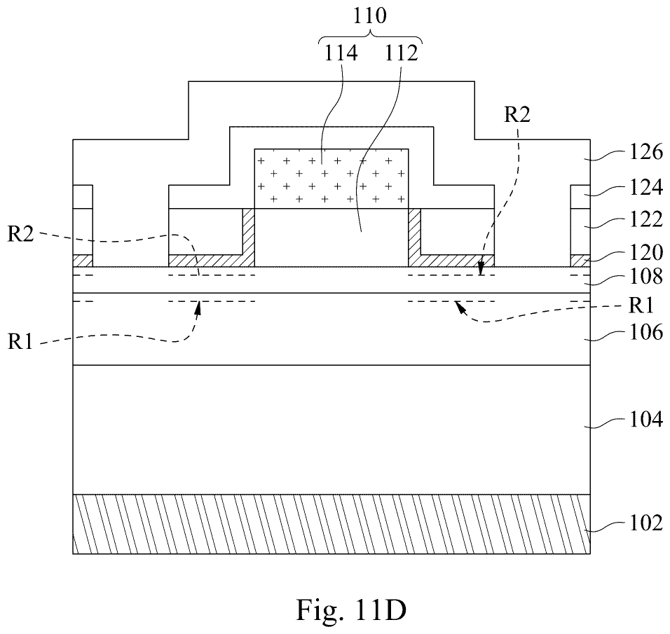

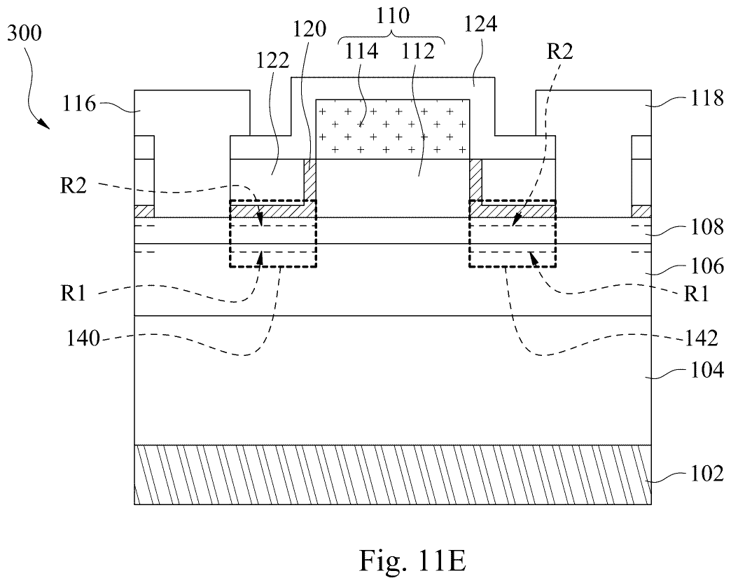

A manufacturing method of the high electron mobility transistor 300 of the present disclosure is described in more detail with the drawings and the embodiments below. Please refer to FIGS. 1, 6, 8, 10, 11A, 11B, 11C, 11D and 11E. FIG. 10 shows a flow chart of a manufacturing method 400 of a high electron mobility transistor according to a fourth embodiment of the present disclosure. FIG. 11A shows a cross-sectional view of Step S41 of obtaining a semiconductor structure 100 of the manufacturing method 400 of the high electron mobility transistor in FIG. 10. FIG. 11B shows a cross-sectional view of Step S42 of depositing a protection layer 124 of the manufacturing method 400 of the high electron mobility transistor in FIG. 10. FIG. 11C shows a schematic cross-sectional view of Step S43 of forming a first opening OP1 and a second opening OP2 of the manufacturing method 400 of the high electron mobility transistor in FIG. 10. FIG. 11D shows a schematic cross-sectional view of a first sub-step of Step S44 of forming a drain electrode 116 and a source electrode 118 of the manufacturing method 400 of the high electron mobility transistor in FIG. 10. FIG. 11E shows a schematic cross-sectional view of a second sub-step of Step S44 of forming the drain electrode 116 and the source electrode 118 of the manufacturing method 400 of the high electron mobility transistor in FIG. 10.

As shown in FIG. 10, the manufacturing method 400 of the high electron mobility transistor (hereinafter referred to as “the manufacturing method 400”) can be used to manufacture the high electron mobility transistor 300 of FIG. 8, and includes Step S41, Step S42, Step S43 and Step S44.

As shown in FIGS. 6, 10 and 11A, Step S41: obtaining the semiconductor structure 100 of FIG. 1. In some embodiments, Step S41 can include Step S21, Step S22, Step S23, Step S24, Step S25 and Step S26 in the manufacturing method 200 of FIG. 6, and is not described again herein.

As shown in FIGS. 10 and 11B, Step S42: depositing a protection layer 124 through the deposition process to cover a part of the first passivation layer 120, the second passivation layer 122 and the gate electrode 114. In step S42, the protection layer 124 can be conformally formed over the part of the first passivation layer 120, the second passivation layer 122 and the gate electrode 114, and the deposition process can be, for example, spin coating process, chemical vapor deposition (CVD) process, physical vapor deposition (PVD) process, atomic layer deposition (ALD) process or other suitable deposition processes.

As shown in FIGS. 10 and 11C, Step S43: etching the first passivation layer 120, the second passivation layer 122 and the protection layer 124 to form a first opening OP1 and a second opening OP2 through an etching process, wherein the etching process can be an anisotropic etching process, and the etching depths of the first opening OP1 and the second opening OP2 are the same. In step S43, two preset positions corresponding to the first opening OP1 and the second opening OP2 can be pattern-defined through a photolithography process, and then the first passivation layer 120, the second passivation layer 122 and the protection layer 124 are removed based on the preset positions through the etching process. In some embodiments, Step S43 can include etch the first passivation layer 120, the second passivation layer 122 and the protective layer 124 through an anisotropic dry etching process until they are aligned with the surface of the barrier layer 108 to form two recesses. In other embodiments, the first passivation layer, the second passivation layer and the protective layer can also be etched downward to the channel layer, and the etched portion of the channel layer can be re-epitaxially grown to produce a high-concentration doping channel layer, thereby reducing contact resistance.

As shown in FIGS. 10, 11C, 11D and 11E, Step S44: forming a drain electrode 116 on the barrier layer 108 and in the first opening OP1, and forming a source electrode 118 on the barrier layer 108 and in the second opening OP2 through a deposition process. In some embodiments, Step S44 can include a first sub-step and a second sub-step. The first sub-step is to conformally form a conductive layer 126 to cover the protection layer 124, the first opening OP1 and the second opening OP2 through the deposition process (as shown in FIG. 11D). The material of the conductive layer 126 can be a conductive metal material, which can be but is not limited to, silver (Ag), aluminum (Al), tungsten (W), nickel (Ni), gold (Au), titanium (Ti), titanium nitride (TiN), titanium aluminum nitride (TiAlN) or other suitable metal materials and combinations thereof. The deposition process for forming the conductive layer 126 can be, for example, chemical vapor deposition (CVD), physical vapor deposition (PVD), electroplating or other suitable deposition process. The second sub-step is to perform a photolithography process and an etching process to form a patterned mask (not shown) on the conductive layer 126, and etch the portion of the conductive layer 126 that is not covered by the patterned mask to form the drain electrode 116 and the source electrode 118 (as shown in FIG. 11E). Thus, the high electron mobility transistor 300 manufactured by the manufacturing method 400 of the present disclosure can be an E-mode HEMT without using p-GaN gate structure. In addition, the energy band structure below the first passivation layer 120 can be adjusted by depositing the first passivation layer 120 on the barrier layer 108, so that the first two-dimensional electron gas regions R1 and the second two-dimensional electron gas regions R2 are formed in the first access region 140 and the second access region 142 to achieve the characteristics of ultra-low voltage input and dual channel.

According to the aforementioned embodiments and examples, the advantages of the semiconductor structure and the manufacturing method thereof and the high electron mobility transistor and the manufacturing method thereof of the present disclosure are described as follows.
1. The semiconductor structure not only has great manufacturing repeatability, but also can reduce the two-dimensional electron gas by thinning the thickness of the barrier layer and reducing the aluminum atom concentration of the barrier layer, so that the high electron mobility transistors including the semiconductor structure have the characteristics of enhancement-mode transistors.
2. Using the undoped gallium nitride layer as part of the gate structure can increase the threshold voltage of high electron mobility transistor.
3. Using the annealing process to recrystallize the first passivation layer disposed on the barrier layer, so that the first passivation layer can adjust the energy band structure below it. Therefore, the first two-dimensional electron gas regions and the second two-dimensional electron gas regions are generated in both the first access region and the second access region to achieve dual channel effect, thereby improving device performance and making it easy to implement commercial products with ultra-low voltage input.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor structure, comprising:
a substrate;
a channel layer disposed on the substrate;
a barrier layer disposed on the channel layer;
a gate structure disposed on the barrier layer;
a first passivation layer disposed on the barrier layer and in contact with a side surface of the gate structure; and
a second passivation layer disposed on the first passivation layer, wherein a material composition of the second passivation layer is different from a material composition of the first passivation layer;
wherein the channel layer has two first two-dimensional electron gas regions near the barrier layer, and the two first two-dimensional electron gas regions are respectively located on two sides of the gate structure;
wherein the barrier layer has two second two-dimensional electron gas regions near the first passivation layer, and the two second two-dimensional electron gas regions are respectively located on the two sides of the gate structure.

2. The semiconductor structure of claim 1, wherein the barrier layer has a thickness less than 10 nanometers, and the barrier layer is a III-V compound barrier layer.

3. The semiconductor structure of claim 1, wherein the barrier layer is an aluminum gallium nitride (AlGaN) layer, and an aluminum atomic concentration of the barrier layer is less than 10%.

4. The semiconductor structure of claim 1, wherein the gate structure comprises:
a semiconductor layer disposed on the barrier layer; and
a gate electrode disposed on the semiconductor layer.

5. The semiconductor structure of claim 4, wherein the semiconductor layer has a thickness ranging from 30 nanometers to 80 nanometers, and the semiconductor layer is an undoped III-V compound semiconductor layer.

6. The semiconductor structure of claim 4, further comprising:
a buffer layer disposed between the substrate and the channel layer;
wherein the buffer layer, the channel layer, the barrier layer and the semiconductor layer form an epitaxial structure.

7. The semiconductor structure of claim 1, further comprising:
a spacer layer disposed between the channel layer and the barrier layer.

8. A manufacturing method of a semiconductor structure, comprising:
providing a substrate and sequentially epitaxially growing a buffer layer, a channel layer, a barrier layer and a semiconductor layer on the substrate;
depositing a metal layer on the semiconductor layer;
etching the semiconductor layer and the metal layer to form a gate structure on the barrier layer;
sequentially depositing a first passivation layer and a second passivation layer to cover the barrier layer and the gate structure;
performing an annealing process to convert the first passivation layer from an amorphous structure to a crystal structure to form two first two-dimensional electron gas regions in the channel layer near the barrier layer and form two second two-dimensional electron gas regions in the barrier layer near the first passivation layer, wherein the two first two-dimensional electron gas regions are respectively located on two sides of the gate structure, and the two second two-dimensional electron gas regions are respectively located on the two sides of the gate structure; and
etching the first passivation layer and the second passivation layer to expose a gate electrode of the gate structure.

9. The manufacturing method of the semiconductor structure of claim 8, wherein the barrier layer has a thickness less than 10 nanometers, the barrier layer is an aluminum gallium nitride (AlGaN) layer, and an aluminum atomic concentration of the barrier layer is less than 10%.

10. The manufacturing method of the semiconductor structure of claim 8, wherein the semiconductor layer has a thickness ranging from 30 nanometers to 80 nanometers, and the semiconductor layer is an undoped III-V compound semiconductor layer.

11. A high electron mobility transistor, comprising:
a substrate;
a channel layer disposed on the substrate;
a barrier layer disposed on the channel layer;
a drain electrode disposed on the barrier layer;
a source electrode disposed on the barrier layer;
a gate structure disposed on the barrier layer and located between the drain electrode and the source electrode;
a first passivation layer disposed on the barrier layer;
a second passivation layer disposed on the first passivation layer; and
a protection layer covering the second passivation layer and the gate structure;
wherein the channel layer has two first two-dimensional electron gas regions near the barrier layer, and the two first two-dimensional electron gas regions are respectively located on two sides of the gate structure;
wherein the barrier layer has two second two-dimensional electron gas regions near the first passivation layer, and the two second two-dimensional electron gas regions are respectively located on the two sides of the gate structure.

12. The high electron mobility transistor of claim 11, wherein the barrier layer has a thickness less than 10 nanometers, and the barrier layer is a III-V compound barrier layer.

13. The high electron mobility transistor of claim 11, wherein the barrier layer is an aluminum gallium nitride (AlGaN) layer, and an aluminum atomic concentration of the barrier layer is less than 10%.

14. The high electron mobility transistor of claim 11, wherein the gate structure comprises:
a semiconductor layer disposed on the barrier layer; and
a gate electrode disposed on the semiconductor layer.

15. The high electron mobility transistor of claim 14, wherein the semiconductor layer has a thickness ranging from 30 nanometers to 80 nanometers, and the semiconductor layer is an undoped III-V compound semiconductor layer.

16. The high electron mobility transistor of claim 14, further comprising:
a buffer layer disposed between the substrate and the channel layer, wherein the buffer layer, the channel layer, the barrier layer and the semiconductor layer form an epitaxial structure;
a spacer layer disposed between the channel layer and the barrier layer; and
a gate spacer disposed on the semiconductor layer and in contact with two opposite sidewalls of the gate electrode.

17. The high electron mobility transistor of claim 11, wherein a first access region is formed between the drain electrode and the gate structure, a second access region is formed between the source electrode and the gate structure, the two first two-dimensional electron gas regions are respectively located in the first access region and the second access region, and the two second two-dimensional electron gas regions are respectively located in the first access region and the second access region.

18. A manufacturing method of a high electron mobility transistor, comprising:
providing a substrate and sequentially epitaxially growing a buffer layer, a channel layer, a barrier layer and a semiconductor layer on the substrate;
depositing a metal layer on the semiconductor layer;
etching the semiconductor layer and the metal layer to form a gate structure on the barrier layer;
sequentially depositing a first passivation layer and a second passivation layer to cover the barrier layer and the gate structure;
performing an annealing process to convert the first passivation layer from an amorphous structure to a crystal structure to form two first two-dimensional electron gas regions in the channel layer near the barrier layer and form two second two-dimensional electron gas regions in the barrier layer near the first passivation layer, wherein the two first two-dimensional electron gas regions are respectively located on two sides of the gate structure, and the two second two-dimensional electron gas regions are respectively located on the two sides of the gate structure;
etching the first passivation layer and the second passivation layer to expose a gate electrode of the gate structure;
depositing a protection layer to cover the second passivation layer and the gate electrode;
etching the first passivation layer, the second passivation layer and the protection layer to form a first opening and a second opening; and
forming a drain electrode on the barrier layer and in the first opening, and forming a source electrode on the barrier layer and in the second opening.

19. The manufacturing method of the high electron mobility transistor of claim 18, wherein the barrier layer has a thickness less than 10 nanometers, the barrier layer is an aluminum gallium nitride (AlGaN) layer, and an aluminum atomic concentration of the barrier layer is less than 10%.

20. The manufacturing method of the high electron mobility transistor of claim 18, wherein the semiconductor layer has a thickness ranging from 30 nanometers to 80 nanometers, and the semiconductor layer is an undoped III-V compound semiconductor layer.
